(19) United States
(12) Patent Application Publication
(10) Pub. No.: US 2020/0066959 A1
(43) Pub. Date: Feb. 27, 2020

(54) STRAIN-INDUCED TOPOLOGICAL TRANSFORMATION OF THERMOELECTRIC RESPONSIVE THIN FILMS

(71) Applicant: KING ABDULLAH UNIVERSITY OF SCIENCE AND TECHNOLOGY, Thuwal (SA)

(72) Inventors: Muhammad Mustafa HUSSAIN, Austin, TX (US); Devendra SINGH, Thuwal (SA)

(21) Appl. No.: 16/344,108

(22) PCT Filed: Nov. 28, 2017
(86) PCT No.: PCT/IB2017/057467

§ 371 Date: Apr. 23, 2019

Related U.S. Application Data
(60) Provisional application No. 62/429,185, filed on Dec. 2, 2016.

(51) Int. Cl. H01L 35/34; H01L 35/32

(52) U.S. Cl. CPC H01L 35/34; H01L 35/32

(57) ABSTRACT

A three-dimensional structure may be obtained from a two-dimensional thin film by applying a stressor layer to the two-dimensional thin film and releasing the thin film from a support substrate. Such a three-dimensional structure may include a thermoelectric responsive material for forming a thermoelectric generator (TEG). A manufacturing process for the transformation from 2-D to 3-D may use a polymer stressor layer deposited on the thermoelectric responsive thin film. The combination thermoelectric responsive layer and stressor layer can be released from a carrier, after which the stressor layer causes the thermoelectric responsive layer to curl. The curl can cause the thermoelectric responsive layer to roll up during the release from the carrier to form a tubular structure.

### CROSS-REFERENCE TO RELATED APPLICATIONS

This application is a continuation of, and claims priority from, U.S. Provisional Patent Application No. 62/429,185, filed on Dec. 2, 2016, entitled “STRAIN-INDUCED TOPOLOGICAL TRANSFORMATION OF THERMOELECTRIC THIN FILMS”, the disclosure of which is incorporated here by reference.

### FIELD OF THE DISCLOSURE

The instant disclosure relates to thermoelectric responsive devices. More specifically, portions of this disclosure relate to three-dimensional thermoelectric responsive components, such as cylindrical thermoelectric responsive components, and a method for manufacturing such thermoelectric responsive components.

### BACKGROUND

One of the few common characteristics of all electronics is that they all generate heat because of the workings of the underlying circuitry. Because electronics are a staple component in our everyday lives and the number of new electronics available in the market increases each year, a significant amount of heat is generated each year from electronics alone. Heat is also generated from numerous sources other than electronics, including the human body. This generated heat, also referred to as “waste heat,” is a ubiquitous and very accessible energy resource. Thus, waste heat is recognized as a potential environmentally friendly energy source capable of supporting increasing energy demand.

Thermoelectric generators (TEGs) are one conventional device used to harvest this waste heat. Thermoelectric generators (TEGs) use a thermoelectric responsive material, which transforms a heat gradient (i.e., temperature differences between two ends of the material) to energy and transfer the energy to another location for use by an electronic device. Some conventional thermoelectric responsive materials are thin film depositions of inorganic semiconductor of Telluride and its alloys. Conventional techniques used to fabricate thermoelectric responsive thin films include physical vapor deposition (PVD), metal organic chemical vapor deposition (MOCVD), and molecular beam epitaxy (MBE). Compared to MOCVD or MBE, physical sputtering based technique is economical and clean with its high throughput and reliability. However, sputter deposition techniques have conventionally been restricted to the deposition of only a small amount of material in its vacuum condition. These thin films can be deposited by lateral deposition or coating using known and reliable techniques. However, these thin films are limited in shape by their flat film shape. Furthermore, these thin films have in-plane conduction that reduces the thermal gradient across the material and thus reduces the efficiency of the TEG or other thermoelectric responsive device.

Although shortcomings of prior art thermoelectric generators are described above, these shortcomings are not the only shortcomings solved by the invention described below. Further, the invention described below does not necessarily solve each and every mentioned shortcoming. Rather, the background material described above is intended to provide an overview of problems related to certain components, such as thermoelectric generators (TEGs), resulting from their two-dimensional shape and/or limited manufacturing processes for forming three-dimensional shapes.

### SUMMARY

A thermoelectric responsive component without in-plane conduction geometry may be fabricated to produce a thermoelectric responsive component with better efficiency and more flexibility than conventional thermoelectric responsive components. For example, a cylindrical shape, or tube or other three-dimensional structure, thermoelectric responsive component may be manufactured through a combination and sequence of thin film deposition processes. The use of thin film processing techniques reduces the complexity and cost and increases the yield of three-dimensional shaped thermoelectric responsive components. The thermoelectric responsive layer may be first formed on a carrier, such as a silicon substrate, and then released from the carrier. A stressor layer in contact with a thermoelectric responsive layer may apply a stress that causes curling of the thermoelectric responsive layer during its release from the carrier. The released thermoelectric responsive layer thus curls to form a cylindrical shape.

According to an embodiment, there is a method, which involves depositing a functional layer on a sacrificial layer, wherein the functional layer and the sacrificial layer are two-dimensional thin films and the sacrificial layer is arranged on a carrier, depositing a stressor layer on the functional layer, and etching at least a portion of the sacrificial layer to release a portion of the functional layer from the carrier to begin forming a three-dimensional structure.

According to another embodiment, there is an apparatus, which includes a component forming a three-dimensional shape, wherein the component comprises a functional layer in contact with a stressor layer, wherein a stress applied by the stressor layer to the functional layer is at least partially responsible for the three-dimensional shape.

According to yet another embodiment, there is an apparatus, which includes a stressor layer configured in a three-dimensional shape and a functional layer attached to and enclosing the stressor layer. An inner diameter of the three-dimensional shape depends on a thickness of the stressor layer

Although processes for forming thermoelectric responsive components, such as thermoelectric generators, are described herein, the manufacturing methods described herein are not limited to only forming thermoelectric responsive components. Rather, the described manufacturing methods and manufactured apparatuses may be useful in other components. Instead of a thermoelectric responsive layer in contact with a stressor layer, any functional layer may be formed in contact with a stressor layer that applies a stress to the functional layer. In the absence of a counterforce, such as provided by a substrate underneath the functional layer and stressor layer, the functional layer may form a three-dimensional shape. Likewise, although the process of forming a single three-dimensional shape may be described in some aspects of the disclosure, the manufacturing process may be applied to form arrays of three-dimensional shapes of any function.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the concepts and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features that are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the disclosed systems and methods, reference is now made to the following descriptions taken in conjunction with the accompanying drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1A is a perspective view of a carrier with deposited thin films for forming a cylindrical thermoelectric responsive component according to some embodiments of the disclosure.

FIG. 1B is a perspective view of a carrier with deposited thin films and a partially etched sacrificial layer resulting in curl of the thermoelectric responsive layer according to some embodiments of the disclosure.

FIG. 2 is a flow chart illustrating a method of manufacturing a three-dimensional component according to some embodiments of the disclosure.

FIGS. 3A-F are perspective view of a manufacturing process for a cylindrical thermoelectric responsive component according to some embodiments of the disclosure.

FIG. 4 is a graph illustrating an effect of stressor layer thickness on tube diameter according to some embodiments of the disclosure.

FIG. 5 is a perspective view of a cylindrical thermoelectric responsive component configured with electrodes according to some embodiments of the disclosure.

FIGS. 6A-6C are graphs illustrating characteristics of a cylindrical thermoelectric responsive component according to some embodiments of the disclosure.

FIG. 7 is a perspective view of a cylindrical thermoelectric responsive component wrapped around a cylindrical-shaped component to operate as a thermoelectric generator (TEG) according to some embodiments of the disclosure.

### DETAILED DESCRIPTION

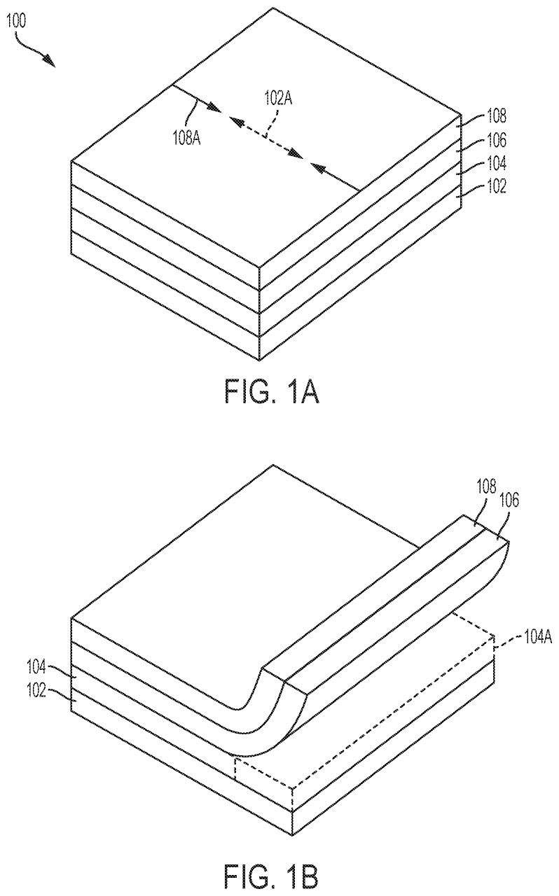

A stressor layer in contact with a thermoelectric responsive layer may apply a stress that creates a force sufficient to curl the thermoelectric responsive layer in the absence of sufficient support from a carrier. The direction and amount of the curl may be controlled by characteristics of the thermoelectric responsive layer and the stressor layer. For example, higher stresses on the thermoelectric responsive layer caused by the stressor layer cause the thermoelectric responsive layer to curl tighter and thus form a cylinder of smaller diameter. Such a higher stress may be created by thin stressor layer. The thermoelectric responsive layer and stressor layer may first be deposited using thin film techniques on a carrier, such as a silicon substrate. The carrier may provide sufficient strength to the thermoelectric responsive layer and the stressor layer such that the stress imposed by the stressor layer does not cause any curling. For example, the carrier may be a thin, rigid carrier or a thick carrier, either of which are example carriers that may inhibit curling of the thermoelectric responsive layer until a desired time. A carrier with deposited layers is shown in FIG. 1A. FIG. 1A is a perspective view of a carrier with deposited thin films for forming a cylindrical thermoelectric responsive component according to some embodiments of the disclosure. A multilayer stack 100 may include a carrier 102, a sacrificial layer 104, a functional layer 106 (which in the illustrated embodiment is a thermoelectric responsive layer), and a stressor layer 108. The carrier 102 may provide a counterforce 102A that opposes a stress 108A applied by the stressor layer 108 to create a push-pull balance on the thermoelectric responsive layer 106. However, the carrier 102 provides sufficient resistance to inhibit or completely prevent physical contortion of the thermoelectric responsive layer 106.

As the sacrificial layer 104 is etched, support from the carrier 102 is lost and the thermoelectric responsive layer 106 begins to curl under stress applied by the stressor layer 108, as shown in FIG. 1B. FIG. 1B is a perspective view of a carrier with deposited thin films and a partially etched sacrificial layer resulting in curl of the thermoelectric responsive layer according to some embodiments of the disclosure. Etching of the sacrificial layer, such as during a wet etch, etches in from the outside edges of the sacrificial layer 104 that are exposed to the wet etch. Directional control may be possible through selection of materials for the sacrificial layer 104 and the etchant, whether wet or dry etchant, and/or through orientation of the carrier 102 during etching. The removed portion 104A of the sacrificial layer 104 releases the thermoelectric responsive layer 106 and stressor layer 108 from the carrier 102. The carrier 102, prior to the removal of portion 104A, provided support to the thermoelectric responsive layer 106 and the stressor layer 108, such that the stress applied by the stressor layer 108 created little or no physical geometrical change in the shape of the thermoelectric responsive layer 106. After removal of portion 104A, the primary force acting upon the thermoelectric responsive layer 106 is stress applied by the stressor layer 108. That applied stress then causes the thermoelectric responsive layer 106, and attached stressor layer 108, to begin curling. The stressor layer 108 may be selected, deposited, and/or treated in such a manner to obtain a compressive stress that pulls the thermoelectric responsive layer 106 towards a center of the carrier 102 or away from a removed potion 104A in the absence of the carrier 102. As the sacrificial layer 104 continues to be etched and the portion 104A grows, the thermoelectric responsive layer 106 continues to curl at a rate and/or with a diameter proportional to the compressive stress applied by the stressor layer 108. The etching of sacrificial layer 104A can continue until a desired shape for the thermoelectric responsive layer 106 is obtained or until the entire sacrificial layer 104A is etched and the thermoelectric responsive layer 106 is released from the carrier. In some embodiments, a cylindrical roll comprising a multilayer material of the thermoelectric responsive layer 106 and the stressor layer 108 may be obtained from the etching and/or releasing process. In other embodiments, a curled sheet or partial roll or other three-dimensional shape may be obtained comprising a multilayer material of the thermoelectric responsive layer 106 and the stressor layer 108 may be obtained from the etching and/or releasing process.

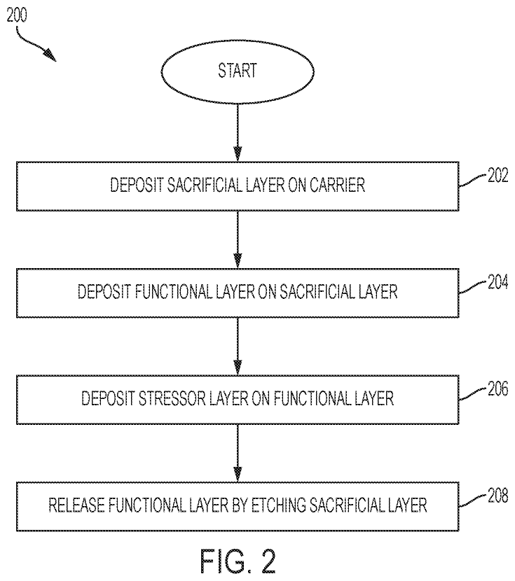

A method for manufacturing a three-dimensional shape starting with a two-dimensional thin film is described in more detail with reference to FIG. 2. FIG. 2 is a flow chart illustrating a method of manufacturing a three-dimensional component according to some embodiments of the disclosure. Although particular embodiments of a manufacturing method for a three-dimensional shape are described with reference to FIG. 2 and throughout this application, the disclosure is not intended to be limited by the details of these described methods. Further, although thermoelectric responsive materials are described throughout, the manufacturing method is not limited to forming three-dimensional shapes from thermoelectric responsive materials, but rather three-dimensional shapes may be formed from any material. Functional layers are described in the example below, and a thermoelectric responsive material is one example of such a functional layer. A “functional layer” refers to any layer, or combination of layers, that provides some functionality other than solely the function of forming the three-dimensional shape.

A method 200 begins at block 202 with depositing a sacrificial layer on a carrier. The carrier may be a wafer, a plate, or other base material. The carrier may be selected to have sufficient strength to counter the compressive stress that will be applied to a subsequently deposited functional layer by a stressor layer. For example, the carrier may be a silicon substrate, such as a p-type lightly doped silicon formed as a four-inch wafer. In some embodiments, the carrier may be reused for multiple repetitions of the method described in FIG. 2 to form multiple self-rolled thermoelectric responsive tube device structures or other three-dimensional structures. The sacrificial layer deposited on the carrier may be selected from many possible materials. The sacrificial layer material can be selected such that the sacrificial layer can be easily etched without affecting subsequent layers, such as the functional layer and the stressor layer, deposited on the sacrificial layer. That is, the sacrificial layer may have a high etch selectivity compared to other materials being deposited on the carrier. In some embodiments, the sacrificial layer may be a thin layer of silicon dioxide (SiO₂) thermally grown with a thickness of between 100 nm and 1000 nm, or more particularly approximately 300 nm. In some embodiments, the sacrificial layer may include multiple layers or multiple, different layers. In some embodiments, a sacrificial layer may not be present and the functional layer is deposited directly on the carrier, in which the bonding between the functional layer and the carrier can be altered or terminated to release the functional layer and stressor layer directly off from the carrier.

The method 200 continues to block 204 with depositing a functional layer, such as a thermoelectric responsive layer, on the sacrificial layer. The functional layer may include one or more layers that individually or together exhibit thermoelectric effects, i.e., transform a heat gradient between two ends of the layer into energy. When the functional layer is a thermoelectric responsive layer, the thermoelectric responsive layer may create a separation of electric charge in response to temperature differences across the thermoelectric responsive layer. Examples of thermoelectric responsive materials include bismuth telluride (Bi₂Te₃), antimony telluride (Sb₂Te₃), lead telluride alloys (e.g., PbTe), inorganic clathrates, magnesium compounds, silicides, among others. In some embodiments, the thermoelectric responsive layer may be a single thin film with a thickness of between 1 μm and 10 μm, or more particularly approximately 2.5 μm. In some embodiments, the thermoelectric responsive films may have a crystal structure, such as a single crystal structure. In some embodiments, the thermoelectric responsive layer deposition may be performed with sputter deposition with conditions of 5 mTorr sputtering pressure, 10 sccm of Argon gas flow, sputtering power of 32 W, 7 cm distance between the sample and target, and 20 rpm substrate rotation respectively.

The method 200 continues to block 206 with depositing a stressor layer on the functional layer. The stressor layer may include one or more layers that individually or together apply a compressive stress to the functional layer. A desirable characteristic of a material for the stressor layer may be controllable internal stress to allow modification of the deposition of the stressor layer to control the final product of the three-dimensional component. For example, a desirable material may be one in which stress within the stressor layer may be modified by heating to different temperatures or for different durations. Another desirable characteristic of a material for the stressor layer may be compatibility with the functional layer and/or resistance to the etchant used to remove the sacrificial layer. In some embodiments, the stressor layer may be an epoxy-based negative photoresist polymeric material, such as SU-8. SU-8 can be easily processed, has a small thermal conductivity of approximately 0.2 W/mk, has a comparable modulus of elasticity with many of the efficient thermoelectric responsive materials, and has an easily controllable stress. Furthermore, SU-8 is a highly bio-compatible material, is mechanically and chemically stable, is chemically resistive and not dissolvable in acid, has a relatively high thermal stability at temperatures greater than 200° C., and is generally transparent. Deposition of the SU-8 stressor layer may be performed by spin coating application on top of the functional layer. A desired thickness of SU-8 can be obtained by adjusting spin speed and baking time. A post-growth heat treatment (e.g., baking) of the SU-8 layer can be performed to adjust a stress level within the SU-8. In some embodiments, the heat treatment may include heating the carrier, and thus the stressor layer, to a temperature of approximately 95° C.

The method 200 continues to block 208 with etching the sacrificial layer, such as to release at least a portion of the functional layer from the carrier. The etching may result in the dissolving of the sacrificial layer. An etchant, either wet or dry, may be selected to match the sacrificial layer, such that the sacrificial layer is more rapidly etched than other layers, such as the functional layer and stressor layer. One highly-selective etchant is hydrofluoric acid (HF) when the sacrificial layer is silicon dioxide (SiO₂). In some embodiments, to release the bilayer (functional film with stressor layer) in a controlled rolling behavior, the carrier may be immersed in wet hydrofluoric (HF) etchant (having a concentration of approximately 49%) followed by immersion in an aqueous medium (e.g., H₂O).

The method 200 may be adjusted to change properties of the material, shape of the three-dimensional structure, and/or number of structures manufactured in parallel. For example, tube orientation, dimensions, and the number of rotations per roll can be adjusted by modifying the method 200. Furthermore, three-dimensional structures can be assembled in large arrays with uniform shapes and sizes and exceptional spatial placement controlled through post-film deposition lithography. Some examples of such lithography techniques include stereolithography, multiphoton lithography, focused ion beam (FIB) machining, photolithography, and electron-beam lithography. Some examples of three-dimensional shapes formed by such lithography techniques include cones, cylinders, notched cylinders, hour-glass shapes, rectangular prisms, pyramids, spheres, and cuboids.

The carrier may be re-used to repeat the method 200 of FIG. 2 to form additional thermoelectric responsive components without an added cost for more carriers. For example, the method 200 may continue with etching to completely remove the sacrificial layer, the thermoelectric responsive layer, and the stressor layer from the carrier to form a first cylindrical roll of the thermoelectric responsive layer. In some embodiments, the carrier may be cleaned or rinsed to remove residue and prepare the surface for additional films. Then, the method 200 may continue with repeating the steps of depositing a sacrificial layer on the carrier, depositing the thermoelectric responsive layer on the sacrificial layer, depositing a stressor layer on the thermoelectric responsive layer, and etching at least a portion of the sacrificial layer to release a portion of the thermoelectric responsive layer from the carrier to form a second cylindrical roll of the thermoelectric responsive layer.

Sample thermoelectric responsive three-dimensional structures were fabricated according to some of the embodiments described above. The samples were manufactured with a silicon substrate as a carrier, a silicon dioxide layer (SiO₂) as the sacrificial layer, a Sb₂Te₃ layer as the thermoelectric responsive layer, and a SU-8 polymer layer as the stressor layer. The microstructural characteristics of the released thin films were investigated using Scanning Electron Microscopy (SEM) and X-Ray Diffraction (XRD) techniques. The thermal transport properties (e.g., Seebeck coefficient, electrical resistivity, and thermal conductivity) of these thin film-based rolled tubes were carried out with physical property measurement system (PPMS) equipment at various temperatures. Gold-coated copper wires were connected to the thermoelectric responsive component sample with epoxy paste to obtain four contacts to perform the thermoelectric property measurement. The measurements indicate that the characteristics of the thermoelectric responsive layer of the three-dimensional structure are like that of the thin film thermoelectric responsive layer. Crystal structure and the orientation of atomic crystals can be determined using powder x-ray diffraction (XRD) measurement analysis. XRD measurements of a prepared film confirmed the existence of the rhombohedral Sb₂Te₃ phase (JCPDS 15-0874). Furthermore, microscopic studies were carried out to observe the surface morphology of the sputter deposited TE film on SiO₂. The SEM analysis of the films shows uniformly distributed grains with size of around 100 nm.

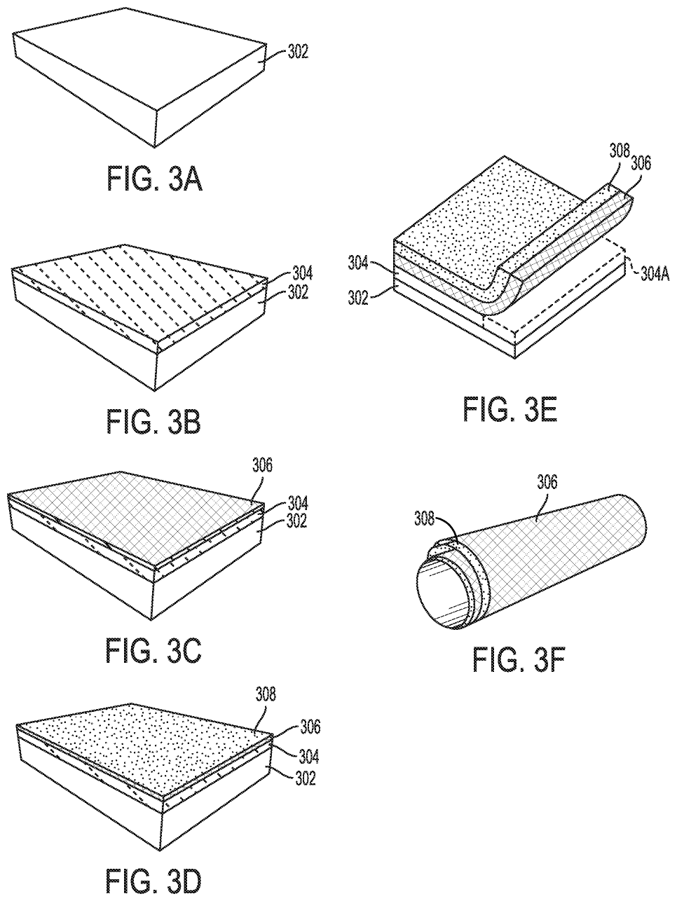

One example manufacturing method for a three-dimensional thermoelectric responsive component is shown in FIGS. 3A-F. FIGS. 3A-F are perspective view of a manufacturing process for a cylindrical thermoelectric responsive component according to some embodiments of the disclosure. A carrier 302 is shown in FIG. 3A. A sacrificial layer 304 is shown on the carrier 302 in FIG. 3B. In some embodiments, layers (not shown) may be positioned between the carrier 302 and the sacrificial layer 304. A thermoelectric responsive film 306 is shown on the sacrificial layer 304 in FIG. 3C. A stressor layer 308 is shown on the thermoelectric responsive layer 306 in FIG. 3D. An etchant may then be applied to the combined structure of FIG. 3D to begin etching the sacrificial layer 304 to release portions of the thermoelectric responsive layer 306 and stressor layer 308. A partial release is shown in FIG. 3E, in which etched portion 304A releases portions of the layers 306 and 308. After an entire film is released from the carrier, a resulting three-dimensional structure, such as a tube in some embodiments, may be obtained as shown in FIG. 3F. A three-dimensional structure, such as that shown in FIG. 3F, may be obtained by completely releasing the sacrificial layer or partially releasing the sacrificial layer.

The shape of the three-dimensional structure obtained by release from the carrier may be determined by characteristics of the layers and the deposition and release process. Thus, the shape of the three-dimensional structure can be controlled by adjusting the manufacturing process or the characteristics of the various layers. In some embodiments, the three-dimensional structure may be partially released from the carrier and then physically cut. The continued etching to partially release and then physically cut may be repeated to produce multiple three-dimensional structures from a single two-dimensional thin film.

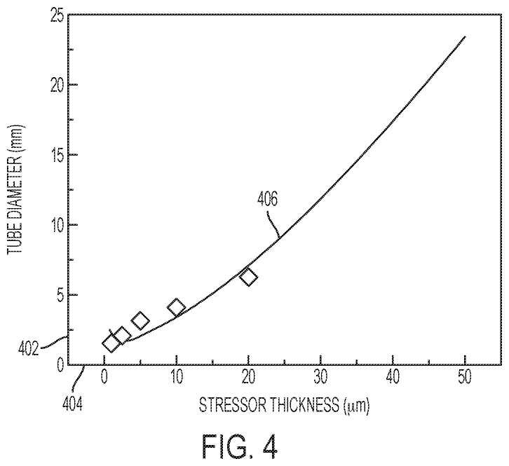

In some embodiments, the diameter of a three-dimensional tube may be controlled by adjusting a thickness of the stressor layer. FIG. 4 is a graph illustrating an effect of stressor layer thickness on tube diameter according to some embodiments of the disclosure. The graph illustrates tube diameter on a y-axis 402 and stressor layer thickness on a x-axis 404. A line 406 shows a curve fit to several measured experimental results describing an approximate relationship between the tube diameter of a three-dimensional tubular thermoelectric responsive component as a function of stressor layer thickness. Larger thicknesses produce less compressive stress on the thermoelectric responsive layer and thus results in a larger tube diameter. Thus, as illustrated in FIG. 4, the inner diameter of the three-dimensional tube depends on the thickness of the stressor layer when a thickness of the functional layer is maintain constant.

A strain-induced semiconductor tube is one possible structure for manipulating the electrons for semiconductor-based heterojunctions. The tubes may be formed spontaneously as a result of energy minimization when a strained planar structure deforms into curved surfaces by strain relaxation. It can be inferred from the strain-induced topological transformation for the self-rolling mechanism, such as those described with reference to FIGS. 1A-B and FIG. 2, that a rolling direction of the bilayer thermoelectric responsive layer and stressor layer may be partly or entirely dependent on the strained layer (and its compressive or tensile stress) deposited on the planar structure. The stressor layer may be deposited on the top of the thermoelectric responsive materials, such that uncontrolled and/or inverted-rolling of rectangular stripe patterns may be avoided. After etching the sacrificial layer, the compressed layer stretches and develops an elastic force F1. On the other hand, the stretched layer compresses and develops an elastic force F2. The directions of forces F1 and F2 are opposite and create a non-zero moment (bending moment) of force M. This bending moment transforms two-dimensional thin film patterns into three-dimensional curved structures. The diameter of the self-rolled tube obtained depends on the thicknesses of the materials involved, their Young's modulus, and differences in stress. The diameter of curvature is obtained by balancing the bending moment on the surface with the flexural rigidity. The equation for the diameter of the tube can be estimated by:

$$D = \frac{( \frac{{E}_{1}}{{E}_{2}} ) {t}_{1}^{4} + 4 {t}_{1}^{3} {t}_{2} + 6 {t}_{1}^{2} {t}_{2}^{2} + 4 {t}_{1} {t}_{2}^{3} + ( \frac{{E}_{2}}{{E}_{1 }} ) {t}_{2}^{4}}{6 Δ {ɛt}_{1} {t}_{2} ( {t}_{1} + {t}_{2} )}$$

where E and t are the Young's modulus and the thickness of the films and subscripts 1 and 2 denote the SU-8 and TEG films, respectively, and Δε denotes the relative stress between the two films. For experimental verification of this model, the thickness of the TEG was kept constant at t₂=2.5 μm. The diameter of the tubes varied with the thickness of the SU-8 stressor layer. The variation in diameter of the tube with thickness of SU-8 layer is shown in FIG. 4. The points denote the experimental values while the solid line shows the theoretical prediction from above equation. The experimental values closely match the theoretical prediction for a relative strain of 0.27%. The growth of the specific strained layers with defined thickness and mismatch strain determines the self-rolled tube diameter. The length of the tube could easily be selected from this data based on the requirement of the thermoelectric responsive component or electronic device incorporating the thermoelectric responsive component. Length of tube of up to or exceeding approximately 4 cm can be achieved through the manufacturing techniques described herein.

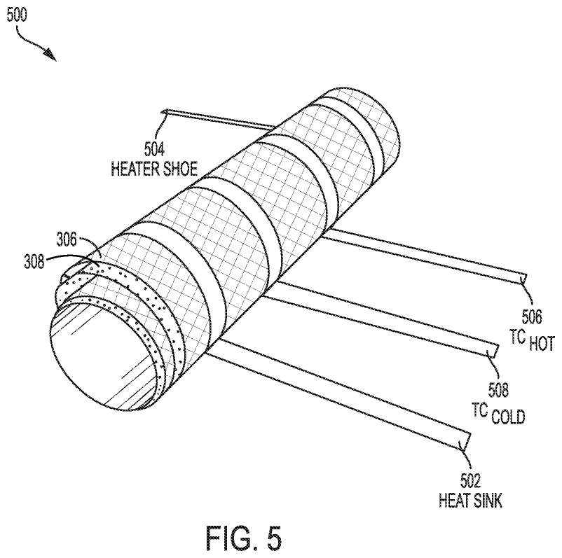

A thermoelectric responsive component may be made from the three-dimensional structure released from the carrier. Some embodiments of a thermoelectric responsive component may include one or more electrodes coupled to different regions of the three-dimensional structure. For example, four electrodes may be coupled as shown in FIG. 5. FIG. 5 is a perspective view of a cylindrical thermoelectric responsive component configured with electrodes according to some embodiments of the disclosure. A thermoelectric responsive component 500 may include a three-dimensional tubular structure having a thermoelectric responsive layer 308 and a stressor layer 306. Four electrodes 502, 504, 506, and 508 may be coupled to the tubular structure. Electrodes 502 and 504 may be used for the heat sink and heater shoe, respectively. Electrodes 506 and 508 may be used for hot and cold thermocouples, respectively. Although FIG. 5 illustrates two loops of layers 306 and 308, the thermoelectric responsive component 500 may include only a single loop of layers 306 and 308 or more than two loops of layers 306 and 308.

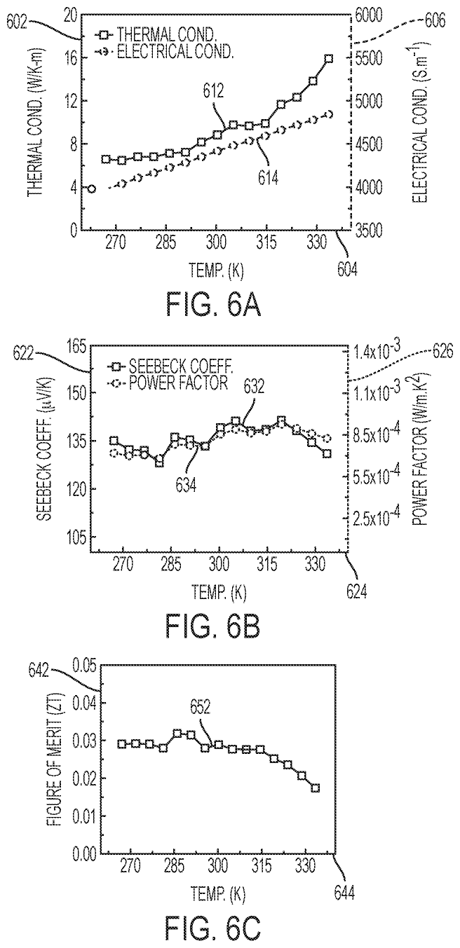

Details regarding the properties of a three-dimensional tubular thermoelectric responsive component are shown in graphs of FIGS. 6A-6C. FIGS. 6A-6C are graphs illustrating characteristics of a cylindrical thermoelectric responsive component according to some embodiments of the disclosure. FIG. 6A shows lines 612 and 614 corresponding to thermal conductivity and electrical conductivity plotted on y-axis 602 and 606, respectively. The lines 612 and 614 show the characteristics as a function of temperature on x-axis 604. FIG. 6B shows lines 632 and 634 corresponding to Seebeck coefficient and power factor plotted on y-axis 622 and 626, respectively. The lines 632 and 634 are shown as a function of temperature on x-axis 624.

FIG. 6C illustrates the figure of merit (ZT) of a three-dimensional tubular thermoelectric responsive component. The efficiency of a thermoelectric responsive device, such as a three-dimensional tubular structure thermoelectric responsive component described herein, may be associated with a dimensionless figure of merit (ZT) of thermoelectric responsive materials, defined as ZT=(α²σ/κ)/T, where α, σ, κ and T are the Seebeck coefficient, electrical conductivity, thermal conductivity and absolute temperature, respectively. The standard thermal transport properties, such as Seebeck coefficient, electrical conductivity, and thermal conductivity, of a Sb₂Te₃-based tube structure was found to be approximately 135 μV/K, 4.4×10³ S/m, and 10 W/K-m, respectively at room temperature. The respective power factor (α²σ) obtained for a sample with those properties may be in the range of (7-9)×10⁻⁴ W/mK² over the temperature range of 270 K-330 K. The figure of merit ZT is around 0.03, which could be further improved. In FIG. 6C line 652 corresponds to figure of merit (ZT) plotted on y-axis 642 as a function of temperature on x-axis 644. As illustrated in FIG. 6C, a three-dimensional tubular structure thermoelectric responsive component, such as those disclosed herein, exhibit a good figure of merit (ZT). The ZT value may be adjusted by using different alloy combination and/or dopant and growth conditions. For example, certain growth conditions may be used to obtain certain desired crystallinities of the thermoelectric responsive material to obtain a desired figure of merit (ZT). As another example, alloying can be used to create defects/vacancies to scatter phonons within the crystal structure to control the thermal conductivity of the thermoelectric responsive material and thus the figure of merit (ZT).

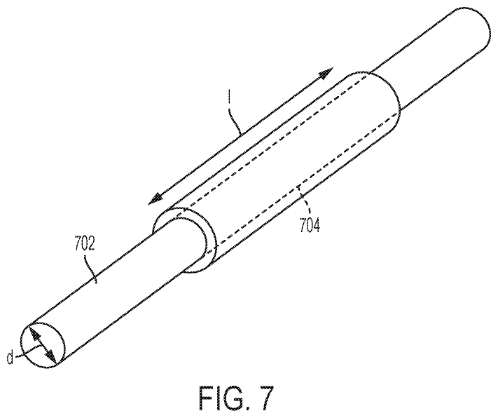

One application for a tubular thermoelectric responsive component is shown in FIG. 7. FIG. 7 is a perspective view of a cylindrical thermoelectric responsive component wrapped around a cylindrical-shaped component to operate as a thermoelectric generator (TEG) according to some embodiments of the disclosure. A tube 702 with a diameter d may radiate heat. For example, the tube 702 may be a copper wire that when energized by a current generates heat difference between two points or a water pipe with warm or hot water that generates a heat difference between two points. A thermoelectric responsive component 704, such as a three-dimensional tube thermoelectric responsive component manufactured as described above, may be wrapped around the tube 702. The thermoelectric responsive component 704 may have a diameter d+Δd slightly larger than the diameter d of the tube 702. The thermoelectric responsive component 704 may have electrodes configured to operate as a thermoelectric generator (TEG). The length I of the thermoelectric responsive component 704 may affect the resulting efficiency of the thermoelectric responsive component 704 when a larger temperature difference between hot and cold can be obtained from a longer distance. The manufacturing techniques described above for forming a three-dimensional structure from a two-dimensional thin film may allow formation of longer length thermoelectric responsive components and at lower costs than previously available.

The methods and structures described above demonstrate the feasibility of a polymer-assisted strain-induced topological transformation of a 2D thin thermoelectric responsive films into non-planar 3D tubular architecture thermoelectric responsive tubes. Parameters of the process and structure that can be adjusted include type of stressor layer, sacrificial layer, thickness of stressor layer, post-growth heat treatment after the deposition of sacrificial layer, type of etchant for the sacrificial layer, and optimization of the time-interval for etching the sacrificial layer. The effect of the stressor layer's thickness was on the self-rolled tube diameters demonstrated. Furthermore, the formation process of strain-induced self-rolled thermoelectric responsive tubes are described in detail. The thermal transport behavior of the rolled thermoelectric responsive tubes are demonstrated as useful for thermoelectric responsive components, with some embodiments having a respective power factor of approximately 8×10⁻⁴ W/mK² at around room temperature. In some embodiments, the self-rolled thermoelectric responsive films can be made into arrays to fabricate thermoelectric generators (TEGs) for energy harvesting applications.

The schematic flow chart diagram of FIG. 2 is generally set forth as a logical flow chart diagram. As such, the depicted order and labeled steps are indicative of one embodiment of the disclosed method. While, for purposes of simplicity of explanation, methodologies are shown and described as a series of acts/blocks, it is to be understood and appreciated that the claimed subject matter is not limited by the number or order of blocks, as some blocks may occur in different orders and/or at substantially the same time with other blocks from what is depicted and described herein. Moreover, not all illustrated blocks may be required to implement methodologies described herein. It is to be appreciated that functionality associated with blocks may be implemented by various aspects of the systems disclosed herein. Other steps and methods may be conceived that are equivalent in function, logic, or effect to one or more steps, or portions thereof, of the illustrated methods. Additionally, the format and symbols employed are provided to explain the logical steps of the methods and are understood not to limit the scope of the methods. Although various arrow types and line types may be employed in the flow chart diagrams, they are understood not to limit the scope of the corresponding methods. Indeed, some arrows or other connectors may be used to indicate only the logical flow of the methods. For instance, an arrow may indicate a waiting or monitoring period of unspecified duration between enumerated steps of the depicted methods. Additionally, the order in which a particular method occurs may or may not strictly adhere to the order of the corresponding steps shown.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present invention, disclosure, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A method, comprising:
depositing a functional layer on a sacrificial layer, wherein the functional layer and the sacrificial layer are two-dimensional thin films and the sacrificial layer is arranged on a carrier;
depositing a stressor layer on the functional layer; and
etching at least a portion of the sacrificial layer to release a portion of the functional layer from the carrier to begin forming a three-dimensional structure.

2. The method of claim 1, further comprising depositing the sacrificial layer on the carrier, wherein the step of depositing a sacrificial layer comprises depositing a silicon oxide layer on a silicon substrate.

3. The method of claim 2, wherein the step of etching at least a portion of the sacrificial layer comprises etching the silicon oxide layer with hydrofluoric acid to release a first portion of the functional layer and the stressor layer such that a stress of the stressor layer applied to the functional layer causes the functional layer and the stressor layer to curl.

4. The method of claim 3, further comprising continuing to etch the sacrificial layer to release a cylindrical roll of the functional layer and the stressor layer formed from curling during the step of etching.

5. The method of claim 1, wherein the step of depositing the functional layer on the sacrificial layer comprises depositing a thermoelectric responsive layer.

6. The method of claim 1, wherein the thermoelectric responsive layer includes telluride.

7. The method of claim 1, wherein the step of depositing the stressor layer on the functional layer comprises depositing a first material on the functional layer; and treating the first material to obtain a desired stress within the first material to form the stressor layer.

8. The method of claim 1, further comprising:
continue etching to remove the sacrificial layer, the functional layer, and the stressor layer from the carrier to form a first cylindrical roll of the functional layer; and
repeating the steps of depositing a sacrificial layer on the carrier, depositing the functional layer on the sacrificial layer, depositing a stressor layer on the functional layer, and etching at least a portion of the sacrificial layer to release a portion of the functional layer from the carrier to form a second cylindrical roll of the functional layer.

9. An apparatus, comprising:
a component forming a three-dimensional shape, wherein the component comprises a functional layer in contact with a stressor layer, wherein a stress applied by the stressor layer to the functional layer is at least partially responsible for the three-dimensional shape.

10. The apparatus of claim 9, wherein the three-dimensional shape is a tube.

11. The apparatus of claim 9, wherein the functional layer comprises a thermoelectric responsive layer.

12. The apparatus of claim 11, wherein the thermoelectric responsive layer includes telluride.

13. apparatus of claim 9, wherein the stressor layer comprises a polymer.

14. An apparatus, comprising:
a stressor layer configured in a three-dimensional shape; and
a functional layer attached to and enclosing the stressor layer,
wherein an inner diameter of the three-dimensional shape depends on a thickness of the stressor layer.

15. The apparatus of claim 14, wherein the inner diameter of the three-dimensional shape also depends on a thickness of the functional layer.

16. The apparatus of claim 14, wherein the stressor layer comprises a polymer.

17. The apparatus of claim 14, wherein the functional layer comprises a thermoelectric responsive layer.

18. The apparatus of claim 17, wherein the thermoelectric responsive layer includes telluride.

19. The apparatus of claim 17, further comprising:
a tube having a temperature gradient, wherein the stressor layer surrounds at least a portion of the tube.

20. The apparatus of claim 17, further comprising:
four electrodes coupled to the thermoelectric responsive layer, wherein the four electrodes include a heat sink electrode, a heater shoe electrode, a hot thermocouple, and a cold thermocouple.
